(19) United States
(12) Patent Application Publication
(10) Pub. No.: US 2008/0116504 A1
(43) Pub. Date: May 22, 2008

(54) Flash Memory Cell and Method for Manufacturing the Same

(76) Inventor: JONG HUN SHIN, Siheung-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/863,437

(22) Filed: Sep. 28, 2007

(30) Foreign Application Priority Data
Nov. 20, 2006 (KR) 10-2006-0114755

(51) Int. Cl. H01L 29/788; H01L 21/336

(52) U.S. Cl. 257/321; 438/261; 257/E29.3; 257/E21.422

(57) ABSTRACT

A flash memory cell and a method for manufacturing the same are provided. The flash memory cell includes a tunnel oxide layer pattern, a floating gate on the tunnel oxide layer pattern, a first nitride layer pattern on the floating gate, an oxide-nitride-oxide (ONO) layer pattern on the first nitride layer pattern, and a control gate on the oxide-nitride-oxide layer pattern.

### CROSS-REFERENCE TO RELATED APPLICATION

The present application claims the benefit under 35 U.S.C. §119 of Korean Patent Application No. 10-2006-0114755, filed Nov. 20, 2006, which is hereby incorporated by reference in its entirety.

### BACKGROUND

Semiconductor memory devices can be classified as volatile memory devices and non-volatile memory devices. Volatile memory includes random access memory (RAM), such as dynamic random access memory (DRAM) and static random access memory (SRAM). Volatile memory can receive and maintain data while power is being applied to it. When the power is removed from the volatile memory, it cannot maintain the data. In contrast, non-volatile memory, such as read only memory (ROM) retains data even if power is not applied.

FIG. 1 shows a typical flash memory cell of the related art. After forming a gate oxide layer 2 on a semiconductor substrate 1, a first polysilicon layer is formed on the gate oxide layer 2 to form a floating gate 3. Then, the second polysilicon layer and an oxide-nitride-oxide (ONO) layer 8 are formed on the floating gate 3, so that the second polysilicon layer is used as a control gate 7. The ONO layer 8 includes an oxide layer 4, a nitride layer 5, and an oxide layer 6. After forming a metal layer and an interlayer insulating layer on the control gate 7, a cell structure is patterned, thereby forming the flash memory cell.

Since semiconductor devices are manufactured with large capacity in a micro-size, they are often highly integrated. However, as a semiconductor device becomes compact, the ONO layer 8 becomes thinner, possibly allowing the electrical characteristics, such as data storage, to be deteriorated. For example, if the surface roughness of the floating gate 3 adjacent to the ONO layer 8 is not good, electron migration occurs through a weak portion of the floating gate, we akening the electrical characteristics of the semiconductor device.

### BRIEF SUMMARY

Embodiments of the present invention provide a flash memory cell and a method for manufacturing the same.

The data storage characteristics of a flash memory cell can be improved by forming a nitride layer on a floating gate such that electrons are inhibited from being emitted from the floating gate.

The flash memory cell can be disposed between a floating gate layer and an oxide-nitride-oxide (ONO) layer, and includes a barrier layer to inhibit electron migration or electron emission from the floating gate layer to the ONO layer.

According to an embodiment, a flash memory cell can include: a semiconductor substrate; a tunnel oxide layer pattern on the semiconductor substrate; a floating gate on the tunnel oxide layer pattern, a first nitride layer pattern on the floating gate; an ONO layer on the first nitride layer pattern; and a control gate on the ONO layer pattern.

According to another embodiment, a method for manufacturing a flash memory cell can include: forming a tunnel oxide layer on a semiconductor substrate; forming a first polysilicon layer on the tunnel oxide layer; implanting impurities into the first polysilicon layer; forming a floating gate and a tunnel oxide layer pattern by etching the first polysilicon layer and the tunnel oxide layer; forming a first nitride layer pattern by nitriding a surface of the floating gate; forming an ONO layer on the first nitride layer; forming a second polysilicon layer on the ONO layer; and forming a control gate and a source/drain by implanting impurities using the second polysilicon layer pattern as an ion implantation mask.

The details of one or more embodiments are set forth in the accompanying drawings and the detailed description. Other features will be apparent to those skilled in the art from the detailed description, the drawings, and the appended claims.

### BRIEF DESCRIPTION OF THE DRAWINGS

FIG. 1 is a cross-sectional view showing a related art flash memory cell.

FIG. 2 is a cross-sectional view showing a flash memory cell according to an embodiment of the present invention.

FIGS. 3 to 8 are cross-sectional views showing a method for manufacturing a flash memory cell according to an embodiment of the present invention.

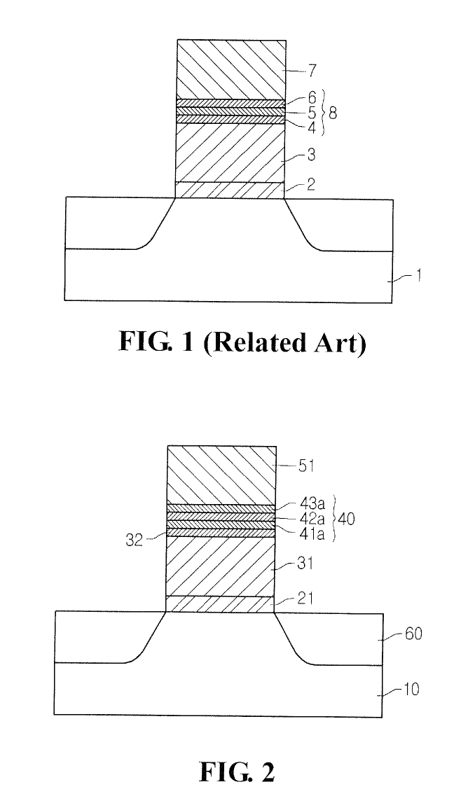

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

Referring to FIG. 2, a source/drain area 60 can be formed in a semiconductor substrate 10. In an embodiment, the semiconductor substrate 10 can be a P-type semiconductor substrate doped with P-type impurity ions at a low concentration. In an alternative embodiment, the semiconductor substrate 10 can be an N-type semiconductor substrate doped with N-type impurity ions at a low concentration. The semiconductor substrate 10 can also include a low-concentration source/drain (LDD) area.

A tunnel oxide layer pattern 21 can be formed on the semiconductor substrate 10. In an embodiment, the tunnel oxide layer pattern 21 can be formed with a thickness of about 100 Å or less. A floating gate 31 can be formed on the tunnel oxide layer pattern 21. A first nitride layer pattern 32 can be formed on the floating gate 31, and an ONO layer pattern 40 can be formed on the first nitride layer pattern 32.

The ONO layer pattern 40 can be formed by sequentially stacking a first oxide layer pattern 41a, the second nitride layer pattern 42a, and a second oxide layer pattern 43a. The first oxide layer pattern 41a can be about 2 times to about 3 times thicker than the first nitride layer pattern 32. In one embodiment, the thickness of the first nitride layer pattern 32 can be in the range of from about 30 Å to about 50 Å.

If the thickness of the first nitride layer pattern 32 is less than ⅓ of the thickness of the first oxide layer pattern 41a, or less than about 30 Å thick, electron migration or electron emission into the ONO layer pattern 40 from the floating gate 31 may occur. Conversely, it may not be advantageous to form the first nitride layer pattern 32 to be thicker than ½ of the thickness of the first oxide layer pattern 41a, or to have a thickness of greater than about 50 Å.

In an embodiment, the thickness of the first oxide layer pattern 41a and the second oxide layer pattern 43a can each be in the range of from about 70 Å to about 100 Å. The thickness of the second nitride layer pattern 42a can be in the range of from about 30 Å to about 50 Å. A control gate 51 can be formed on the ONO pattern 40. In addition, a flash memory cell can be formed utilizing the control gate 51.

Hereinafter, a method for manufacturing a flash memory cell according to an embodiment will be described.

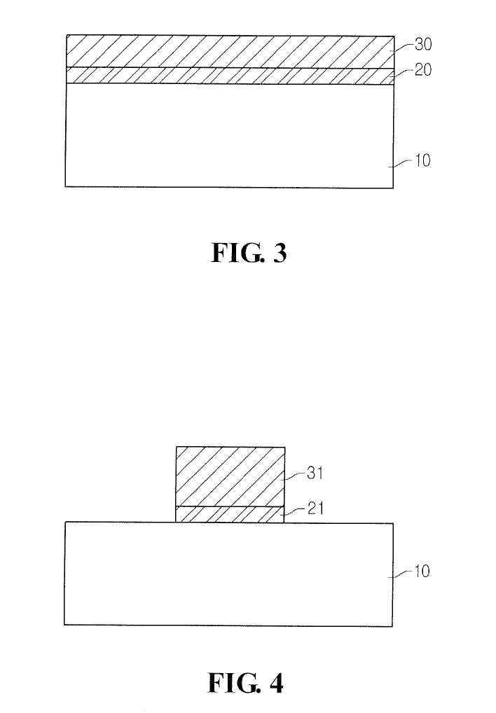

Referring to FIG. 3, a tunnel oxide layer 20 can be formed on a semiconductor substrate 10, and a first polysilicon layer 30 can be formed on the tunnel oxide layer 20. The tunnel oxide layer 20 can be formed by oxidizing the semiconductor substrate 10. The first polysilicon layer 30 can be formed on the tunnel oxide layer 20 through a chemical vapor deposition (CVD) process. In an embodiment, the tunnel oxide layer 20 can have a thickness of about 100 Å or less, and the first polysilicon layer 30 can have a thickness in the range of from about 1500 Å to about 2500 Å.

Then, impurity ions can be implanted into the first polysilicon layer 30. Then, a photoresist film (not shown) can be formed on the first polysilicon layer 30. The photoresist Film can be patterned through a photo process including an exposure and development process, thereby forming a photoresist pattern (not shown) on the first polysilicon layer 30.

The first polysilicon layer 30 and the tunnel oxide layer 20 can be patterned by using the photoresist pattern as an etching mask. Then, the photoresist pattern can be removed. Accordingly, referring to FIG. 4, the floating gate 31 and the tunnel oxide layer pattern 21 can be formed on the semiconductor substrate 10.

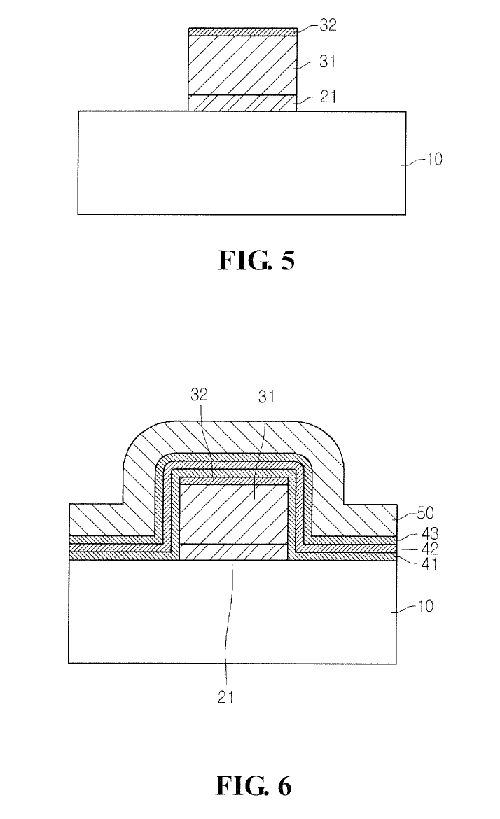

Referring to FIG. 5, the floating gate 31 can be nitrided through plasma nitriding, thereby forming the first nitride layer pattern 32. In an embodiment, the nitride layer pattern 32 can be formed to a thickness ⅓ to ½ the thickness of a first oxide layer pattern formed in a subsequent process. In one embodiment, the thickness of the first nitride layer pattern 32 is in the range of from about 30 Å to about 50 Å.

The first nitride layer pattern 32 can be formed through a plasma process under a nitrogen atmosphere with radio frequency (RF) power supplied in the range of from about 200 W to about 1500 W and a pressure in the range of from about 5 mTorr to about 10 mTorr for a period of time of from about 10 seconds to about 150 seconds.

Referring to FIG. 6, a first oxide layer 41, a second nitride layer 42, a second oxide layer 43, and a second polysilicon layer 50 can be formed on the first nitride layer pattern 32. In an embodiment, the thickness of the first oxide layer 41 and the second oxide layer 43 can each be in the range of from about 70 Å to about 100 Å. The thickness of the second nitride layer 42 can be in the range of from about 30 Å to about 50 Å. In addition, the thickness of the second polysilicon layer 50 can be in the range of from about 1500 Å to about 2500 Å.

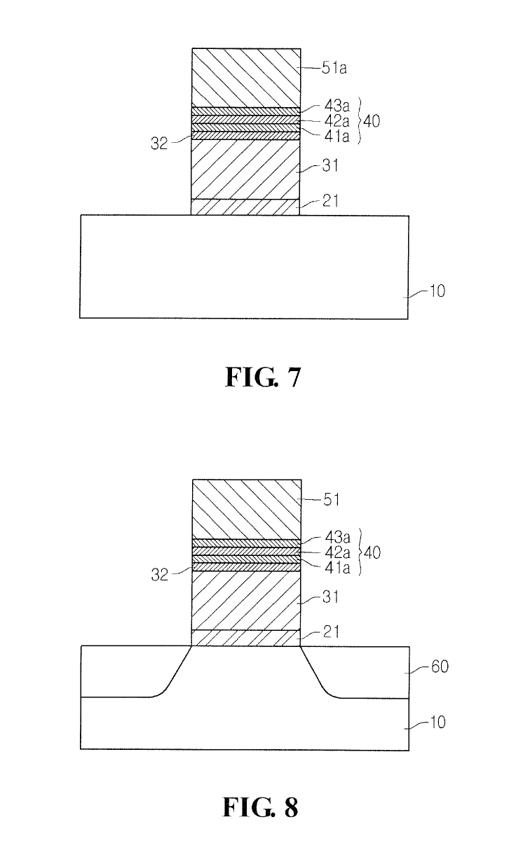

Then, a photoresist film (not shown) can be formed on the second polysilicon layer 50 and patterned through an exposure and development process, thereby forming a photoresist pattern (not shown). An etching process may be performed using the photoresist pattern as an etching mask, thereby forming the first oxide layer pattern 41a, the second nitride layer pattern 42a, the second oxide layer pattern 43a, and the second polysilicon layer pattern 51a as shown in FIG. 7.

Referring to FIG. 8, impurity ions can be implanted using the second polysilicon layer pattern 51a (see FIG. 7) as an ion implantation mask, thereby forming a control gate 51 and a source/drain area 60.

In embodiments of the present invention, a nitride layer is formed on a floating gate, thereby inhibiting electrons from being emitted from the floating gate. Accordingly, data storage characteristics of a flash memory cell can be improved, thereby enhancing the overall electrical characteristics of the semiconductor device.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A flash memory cell comprising:
a semiconductor substrate;
a tunnel oxide layer pattern on the semiconductor substrate;
a floating gate on the tunnel oxide layer pattern;
a first nitride layer pattern on the floating gate;
an oxide-nitride-oxide (ONO) layer pattern on the first nitride layer pattern, wherein the ONO layer comprises a first oxide layer pattern, a second nitride layer pattern on the first oxide layer pattern, and a second oxide layer pattern on the second nitride layer pattern; and
a control gate on the ONO layer pattern.

2. The flash memory cell according to claim 1, wherein the first oxide layer pattern is about 2 times to about 3 times thicker than the first nitride layer pattern.

3. The flash memory cell according to claim 1, wherein the first nitride layer pattern has a thickness in a range of from about 30 Å to about 50 Å.

4. The flash memory cell according to claim 3 wherein the first oxide layer pattern has a thickness in a range of from about 70 Å to about 100 Å, and wherein the second oxide layer pattern has a thickness in a range of from about 70 Å to about 100 Å, and wherein the second nitride layer pattern has a thickness in a range of from about 30 Å to about 50 Å.

5. The flash memory cell according to claim 1, wherein the first nitride layer pattern is formed through a plasma nitridation process.

6. A method for manufacturing a flash memory cell, the method comprising:
forming a tunnel oxide layer on a semiconductor substrate;
forming a first polysilicon layer on the tunnel oxide layer;
implanting impurities into the first polysilicon layer;
etching the first polysilicon layer and the tunnel oxide layer to form a floating gate and a tunnel oxide layer pattern;
forming a first nitride layer pattern on the floating gate;
forming a first oxide layer, a second nitride layer, a second oxide layer, and a second polysilicon layer on the first nitride layer pattern;
etching the first oxide layer, the second nitride layer, the second oxide layer, and the second polysilicon layer to form a first oxide layer pattern, a second nitride layer pattern, a second oxide layer pattern, and a second polysilicon layer pattern; and
forming a control gate and a source/drain.

7. The method according to claim 6, wherein the forming a control gate and a source/drain comprises implanting impurities using the second polysilicon layer pattern as an ion implantation mask.

8. The method according to claim 6, wherein forming a first nitride layer pattern comprises nitriding the floating gate.

9. The method according to claim 8, wherein nitriding the floating gate comprises a plasma nitridation process.

10. The method according to claim 9, wherein the plasma nitridation process is performed under a nitrogen atmosphere with radio frequency (RF) power in a range of from about 200 W to about 1500 W and a pressure in a range of from about 5 mTorr to about 10 mTorr.

11. The method according to claim 10, wherein the plasma nitridation process is performed for a period of time in the range of from about 10 seconds to about 150 seconds.

12. The method according to claim 6, wherein the first oxide layer is about 2 times to about 3 times thicker than the first nitride layer pattern.

13. The method according to claim 6, wherein the first nitride layer pattern has a thickness in a range of from about 30 Å to about 50 Å.

14. The method according to claim 13, wherein the first oxide layer pattern has a thickness in a range of from about 70 Å to about 100 Å, and wherein the second oxide layer pattern has a thickness in a range of from about 70 Å to about 100 Å, and wherein the second nitride layer pattern has a thickness in a range of from about 30 Å to about 50 Å

15. The method according to claim 6, wherein the second polysilicon layer pattern has a thickness in the range of from about 1500 Å to about 2500 Å.

16. A flash memory cell comprising a barrier layer between a floating gate layer and an oxide-nitride-oxide (ONO) layer, wherein the barrier layer inhibits electrons from migrating from the floating gate layer into the ONO layer.

17. The lash memory cell according to claim 16, wherein the barrier layer comprises a nitride layer.

18. The flash memory cell according to claim 16, wherein the barrier layer has a thickness in a range of from about 30 Å to about 50 Å.

19. The flash memory cell according to claim 16, wherein the ONO layer comprises an oxide layer directly on the barrier layer, and wherein the thickness of the oxide layer directly on the barrier layer is about 2 times to about 3 times thicker than the barrier layer.

20. The flash memory cell according to claim 16, wherein the barrier layer is formed by nitriding the floating gate layer.
